(19) United States
(12) Patent Application Publication
(10) Pub. No.: US 2024/0410861 A1
(43) Pub. Date: Dec. 12, 2024

(54) REDUCTION OF CROSSTALK IN ROW-COLUMN ADDRESSED ARRAY PROBES

(71) Applicant: EVIDENT CANADA, INC., Québec (CA)

(72) Inventors: Jinchi Zhang, Quebec (CA); Gautier Mahieu, Saint-Augustin-de-desmaures (CA); Frederic Landry, Quebec (CA)

(21) Appl. No.: 18/699,477

(22) PCT Filed: Oct. 21, 2022
(86) PCT No.: PCT/CA2022/051561

§ 371 Date: Apr. 8, 2024

Related U.S. Application Data
(60) Provisional application No. 63/270,687, filed on Oct. 22, 2021.

(51) Int. Cl. G01N 29/24; G01N 29/04; H10N 39/00

(52) U.S. Cl. CPC G01N 29/2437; G01N 29/043; H10N 39/00; G01N 2291/106

(57) ABSTRACT

Techniques for reducing or eliminating cross talk in row-column addressed array (RCA) probes are described. A diode can be connected in series to piezo-composite element in each pixel of the RCA to prevent cross talk. A resistor can also be provided in parallel to the piezo-composite element for discharging purposes and providing DC paths for the forward and backward bias voltages to the diodes. Thus. RCA probes using the techniques disclosed herein can use sub-apertures for, among other things, inspecting longitudinal and transverse flaws, and for more efficient local focusing for an acoustic camera without significant cross talk interference.

### PRIORITY CLAIM

This application claims the benefit of priority to U.S. Provisional Patent Application Ser. No. 63/270,687, filed on Oct. 22, 2021, and entitled “CROSS TALK FREE RCA PROBE,” which is incorporated herein by reference in its entirety.

### TECHNICAL FIELD

The present disclosure generally relates to ultrasound probes for inspecting test objects using a row-column addressed array (“RCA”).

### BACKGROUND

Ultrasound technology can be used for inspecting materials (e.g., pipes) in a non-destructive manner. One application can be detection of flaws or imperfections in a spot weld, a common technique for joining two pieces of metal used in various manufacturing processes. Some inspection techniques, such as using a two-dimensional transducer, can have limitations with respect to inspecting materials. For example, a two-dimensional transducer may present a tradeoff between element quantity, resolution, acoustic frequency, and a lack of focusing.

An RCA (row-column addressed array) probe can greatly reduce the quantity of the connecting cables for a two-dimensional imaging compared to a matrix probe. RCA probes can be used in the medical domain and non-destructive testing domain. However, cross talk in RCA probes can occur when activating sub-apertures (e.g., not grounding all rows or not grounding all columns, addressing a subset of pixels). Cross talk can lead to serious performance issues and can prevents RCA probes from unexpected beam focusing. The cross talk can seriously compromise the scan of a sub-aperture. The use of sub-apertures can be advantageous for inspecting longitudinal and transverse flaws, and for more efficient local focusing an acoustic camera used, for example, for spot weld inspection.

### BRIEF DESCRIPTION OF THE DRAWINGS

Various ones of the appended drawings merely illustrate example implementations of the present disclosure and should not be considered as limiting its scope.

FIG. 1 illustrates a schematic diagram of an RCA probe according to some examples of the present disclosure.

FIG. 2A illustrates a transmission configuration of a RCA probe according to some examples of the present disclosure.

FIG. 2B illustrates a transmission configuration of a RCA probe according to some examples of the present disclosure.

FIG. 3A illustrates a reception configuration of a RCA probe according to some examples of the present disclosure.

FIG. 3B illustrates a reception configuration of a RCA probe according to some examples of the present disclosure.

FIG. 4 illustrates an RCA probe in an integrated package according to some examples of the present disclosure.

FIG. 5 illustrates an RCA probe assembly according to some examples of the present disclosure.

FIG. 6 illustrates an RCA probe assembly with according to some examples of the present disclosure.

FIG. 7 illustrates example portions of a probe assembly according to some examples of the present disclosure.

### DETAILED DESCRIPTION

Techniques for reducing or eliminating cross talk in row-column addressed array (RCA) probes are disclosed herein. A diode can be connected in series to piezo-composite element in each pixel of the RCA to prevent cross talk. A resistor can also be provided in parallel to the piezo-composite element for biasing the diode and discharging the piezo-composite element and providing DC paths for the forward and backward bias voltages to the diodes. Thus, RCA probes using the techniques disclosed herein can use sub-apertures for, among other things, inspecting longitudinal and transverse flaws, and for more efficient local focusing for an acoustic camera without significant cross talk interference.

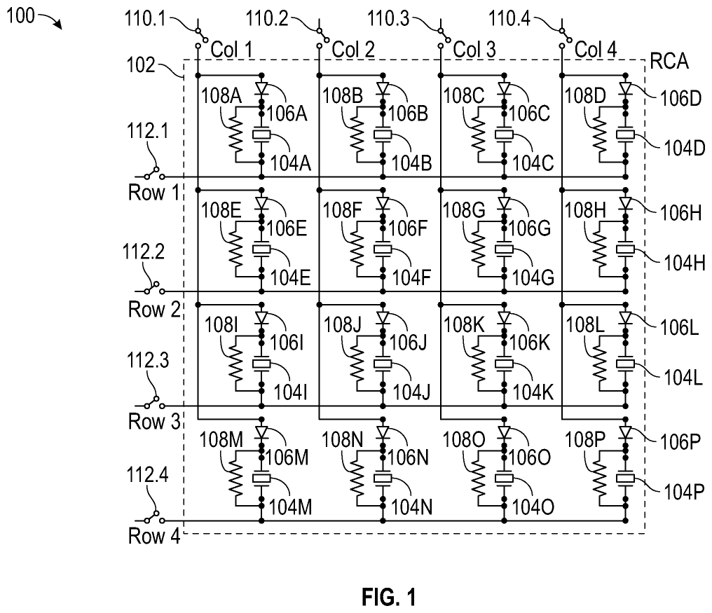

FIG. 1 illustrates a schematic diagram of an RCA probe 100 according to some examples of the present disclosure. The RCA probe 100 may include an RCA 102, column switches 110.1-110.4, and row switches 112.1-112.4. The RCA 102 may include column and row electrodes arranged in a matrix. The row electrodes and column electrodes may be arranged substantially perpendicular or orthogonal to each other, forming an array with elements or pixels provided at the intersections of the row and column electrodes. The row electrodes may include n number of line electrodes arranged in parallel, and the column electrodes may include m number of line electrodes arranged in parallel; hence, the RCA 102 may include n by m (n×m) array of elements or pixels.

Respective pixels may include a piezo-composite element 104, a diode 106, and a resistor 108 (shown as 104A-P, 106A-P, 108A-P, respectively). In the respective pixels, the diode 106 may be connected in series with the piezo-composite element 104. The resistor 108 may be connected in parallel with the piezo-composite element 104. In some examples, the resistors 108A-P may be provided as 1-10k ohm resistors. As explained in further detail below, the diodes 106A-P and resistors 108A-P may reduce or eliminate cross talk between pixels.

Each column electrode may be coupled to a respective column switch 110.1-110.4. Each column switch 110.1-110.4 may have four possible connections, thereby operating the coupled column electrode in one of four states depending on the switch connection: 1) a transmission state, 2) a reception state, 3) a ground state, and 4) a high impedance (float) state.

Each row electrode may be coupled to a respective row switch 112.1-112.4. Each row switch 112.1-112.4 may have four possible connections, thereby operating the coupled row electrode in one of four states depending on the switch connection: 1) a transmission state, 2) a reception state, 3) a ground state, and 4) a high impedance (float) state.

In a transmission state, respective switches may couple the row/column electrode to an excitation signal, e.g., a voltage pulse signal. In a reception state, the respective switch may couple the row/column electrode to an output of the RCA 102. The output of the RCA 102 may be coupled to signal processing components, such as an analog-to-digital converter and a processor, to process the received signal from the RCA 102. For example, the processor may execute a time of flight (ToF) technique using the output of the RCA. In a ground state, the respective switch may couple the row/column electrode to ground, which may be a reference node at a fixed reference potential. In a high impedance state, the respective switch may couple the row/column electrode to a high impedance, such that the coupled row/column electrode may electrically function in substantially an open state (i.e., a floating node).

The column and row switches 110.1-110.4, 112.1-112.4 may be provided as multiplexers, logic devices, or the like. Moreover, different pulse signals may be provided in the transmission state. The different pulse signals may have different magnitudes and/or different duty cycles.

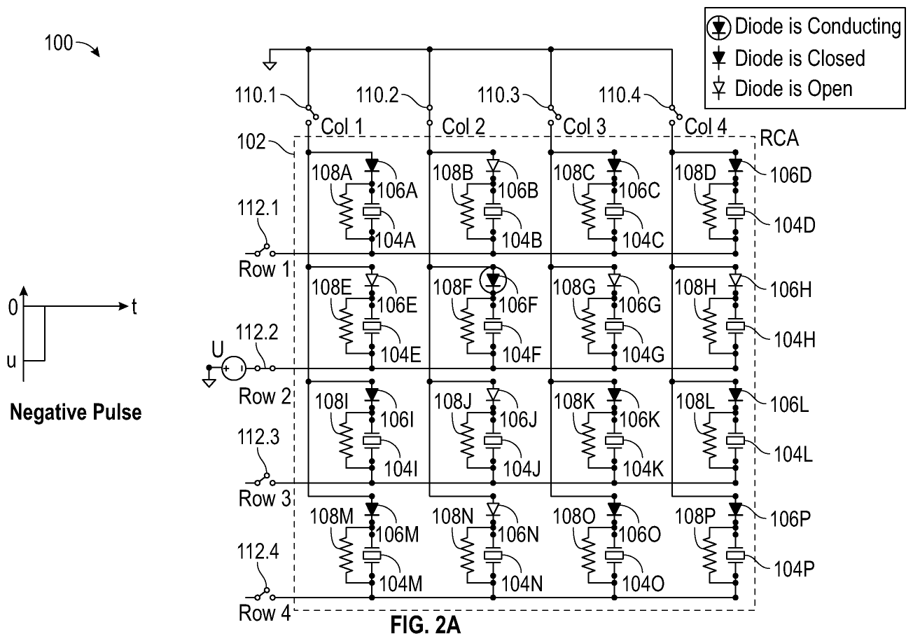

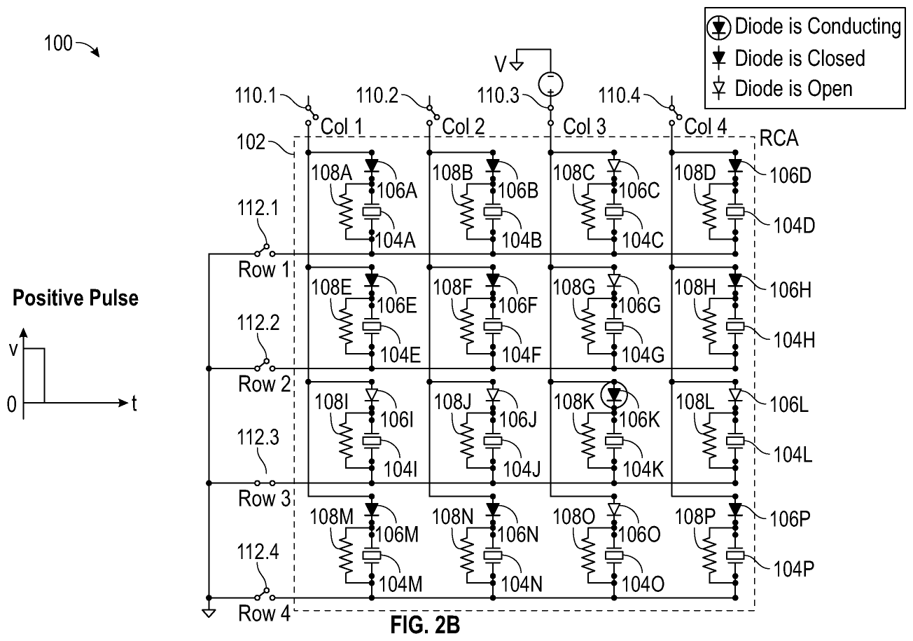

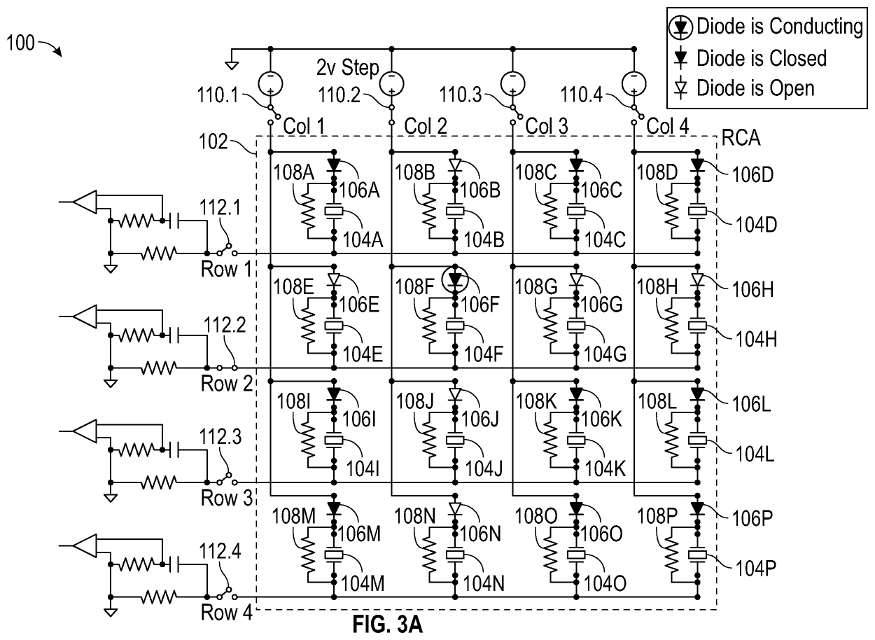

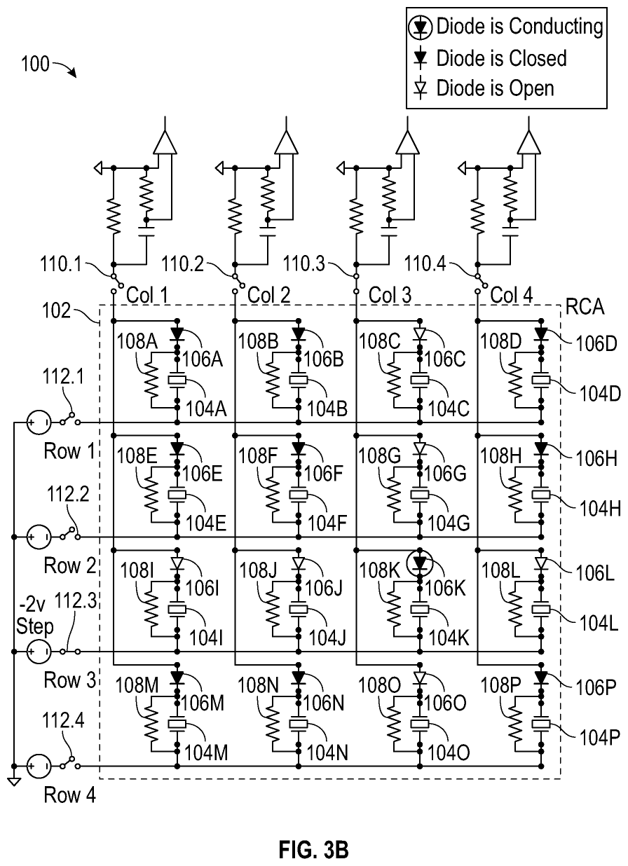

FIGS. 2A and 2B illustrate different transmission configurations of the RCA probe 100 according to examples of the present disclosure. FIG. 3A illustrates a first transmission configuration, where selected row electrode(s) may be driven while selected column electrode(s) may be coupled to ground, such that the intersection of the selected column and row electrodes define the transmission aperture (i.e., sub-aperture). Here, row switch 112.2 is closed setting the selected row electrodes of the second row to a transmission state by coupling to an excitation signal, such as a negative pulse signal, and other row switches 112.1, 112.3, 112.4 may set the remaining row electrodes to a high impedance state. Similarly, column switch 110.2 is closed setting the selected column electrodes to a ground state, and other column switches 110.1, 110.3, 110.4 may set the remaining column electrodes to a high impedance state.

The intersection of the second row and column, in this example, may define the transmission aperture, which here is pixel “F”. That is, an ultrasound wave may be transmitted by the piezo-composite element 104F. The diode 106F, which is in series with piezo-composite element 104F, may be conducting. Other diodes in the RCA 102 may reduce or eliminate cross talk in the non-activated pixels. For example, diodes 106A, 106C, 106D, 106I, 106K, 106L, 106M, 106O, and 106P may be closed and block current from flowing through their respective pixels. The other diodes 106B, 106E, 106G, 106H, 106J, and 106N may remain open as there is no current to block from flowing through their respective pixels. The resistors 108F may discharge the charge stored in the respective piezo-composite element 104F between activations.

FIG. 2B illustrates a second transmission configuration, where selected column electrodes may be driven while selected row electrodes may be coupled to ground, such that the intersection of the selected column and row electrodes define a transmission aperture (i.e., sub-aperture). Here, column switch 110.3 is closed setting the selected row electrodes of the third column to a transmission state by coupling to an excitation signal, such as a positive pulse signal, and other column switches 110.1, 110.2, 110.4 may set the remaining column electrodes to a high impedance state. Similarly, row switch 112.3 is closed setting the selected row electrodes to a ground state, and other row switches 112.1, 112.2, 112.4 may set the remaining row electrodes to a high impedance state.

The intersection of the third row and column, in this example, may define the transmission aperture, which here is pixel “K”. That is, an ultrasound wave may be transmitted by the piezo-composite element 104K. The diode 106K, which is in series with piezo-composite element 104K, may be conducting. Other diodes in the RCA 102 may reduce or eliminate cross talk in the non-activated pixels. For example, diodes 106A, 106B, 106D, 106E, 106H, 106F, 106M, 106N, and 106P may be closed and block current from flowing through their respective pixels; a negative voltage is applied to these diodes thus blocking the current. The other diodes 106C, 106G, 106G, 106I, 106J, 106L, and 106O may remain open as there is no current to block from flowing through their respective pixels; these diodes may be seen as “dummy” diodes since they are floating and do not affect the current path. The resistor 108K may discharge the charge stored in the respective piezo-composite element 104K between activations.

Multiple rows and/or column electrodes may be activated for transmission at the same time. The intersection of the activated rows and column electrodes, in either the first or second transmission configuration, may define the transmission aperture. If there are no delays, the transmission aperture, if it contains a plurality of pixels, may operate as a single sub-aperture transmitting a sound field in the normal direction. Delays may be added for beam steering, for example. The first transmission configuration can generate a beam steering or focusing in perpendicular to the rows. The second transmission configuration can generate a beam steering or focusing in perpendicular to the columns. Moreover, bipolar pulsers may also be used. For example, bipolar pulsers can be used for the first or the second transmission configuration for steering or focusing a beam in the row incidence plane or in the column incidence plane.

FIGS. 3A and 3B illustrate different reception configurations of the RCA probe 100 according to some examples of the present disclosure. FIG. 3A illustrates a first reception configuration, where selected row electrode(s) may be used for reception while selected column electrode(s) may be coupled to a set voltage (e.g., low DC voltage, ground), such that the intersection of the selected row and column electrodes define a reception aperture (i.e., sub-aperture). Here, row switch 112.2 may set the selected row electrodes to a reception state by coupling to an output of the RCA 102, which may include resistors and amplifiers, and other row switches 112.1, 112.3, 112.4 may set the remaining row electrodes to a high impedance state. Similarly, column switch 110.2 is closed setting the selected column electrodes to a set voltage, which in this example is 2V DC, and other column switches 110.1, 110.3, 110.4 may set the remaining column electrodes to a high impedance state.

The intersection of the second row and column, in this example, may define the reception aperture, which here is pixel “F”. That is, an ultrasound wave may be received by the piezo-composite element 104F. The diode 106F, which is in series with piezo-composite element 104F, may be conducting. Other diodes in the RCA 102 may reduce or eliminate cross talk in the non-activated pixels. For example, diodes 106A, 106C, 106D, 106I, 106K, 106L, 106M, 106O, and 106P may be closed and block current from flowing through their respective pixels because they are negatively biased. The other diodes 106B, 106E, 106G, 106H, 106J, and 106N may remain open as there is no current to block from flowing through their respective pixels. The resistor 108F may discharge the charge stored in the respective piezo-composite element 104F between activations. The resistors 108A-108J, 108L-108P may provide the current paths with a backward bias voltage to close the diodes 106A, 106C, 106D, 106I, 106K, 106L, 106M, 106O. Moreover, the resistor 108F may allow a constant DC voltage (e.g., 2V DC) to be applied to the activated pixels. A DC voltage may be used so that the diode 106F may operate in the respective linear zone so that full waveforms can be passed through the diodes. The applied DC voltage may be set just above the threshold of the diode 106F.

FIG. 3B illustrates a second reception configuration, where selected column electrode(s) may be used for reception while selected row electrode(s) may be coupled to a set voltage (e.g., low DC voltage, ground), such that the intersection of the selected row and column electrodes define a reception aperture (i.e., sub-aperture). Here, column switch 110.3 may set the selected column electrodes to a reception state by coupling to an output of the RCA 102, which may include resistors and amplifiers, and other column switches 110.1, 110.2, 110.4 may set the remaining column electrodes to a high impedance state. Similarly, row switch 112.3 is closed setting the selected row electrodes to a set voltage, and other row switches 112.1, 112.2, 112.4 may set the remaining row electrodes to a high impedance state.

The intersection of the third row and column, in this example, may define the reception aperture, which here is pixel “K”. That is, an ultrasound wave may be received by the piezo-composite element 104K. The diode 106K, which is in series with piezo-composite element 104K, may be conducting. Other diodes in the RCA 102 may reduce or eliminate cross talk in the non-activated pixels. For example, diodes 106A, 106B, 106D, 106E, 106H, 106F, 106M, 106N, and 106P may be closed and block current from flowing through their respective pixels because they are negatively biased. The other diodes 106C, 106G, 106G, 106I, 106J, 106L, and 106O may remain open as there is no current to block from flowing through their respective pixels. The resistors 108A-108K may discharge the charge stored in the respective piezo-composite elements 104K between activations. Moreover, the resistors 108A-108K may allow a constant DC voltage (e.g., −2V DC) to be applied to the activated pixels. A DC voltage may be used so that the diodes 106A-106K may operate in the respective linear zone so that full waveforms can be passed through the diodes. The applied DC voltage may be set just above the threshold of the diode 106K. The resistors 108A, 108B, 108D, 108E, 108F, 108H, 108M, 108N, 108P may provide the current paths with a backward bias voltage to close the diodes 106A, 106B, 106D, 106E, 106F, 106H, 106M, 106N, 106P.

Multiple rows and/or column electrodes may be activated for reception at the same time. The intersection of the activated rows and column electrodes, in either the first or second reception configuration, may define the reception aperture. If there are no delays, the reception aperture, if it contains a plurality of pixels, may operate as a single sub-aperture receiving the sound waves in the normal direction. Delays may be added for beam steering, for example. The first reception configuration can receive or focus in the direction perpendicular to the rows. The second reception configuration can receive or focus in the direction perpendicular to the columns. A step DC voltage can be used to operate the RCA probe in the first and second reception configurations.

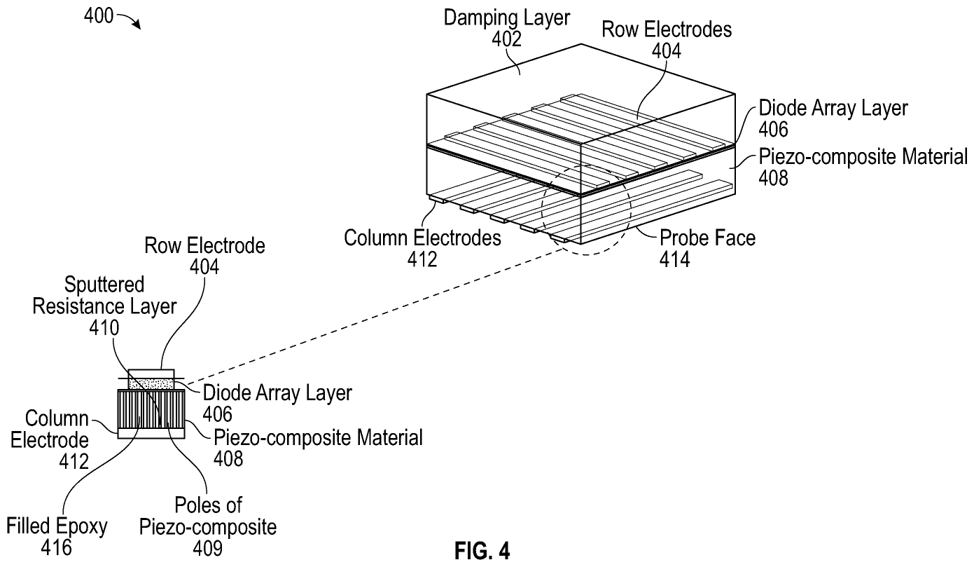

The RCA probe with reduced or eliminated cross talk, as described herein, may be implemented using different techniques. The RCA probe can be provided in an integrated package using thin film technology and/or provided using separate components. FIG. 4 illustrates an RCA probe 400 in an integrated package according to some examples of the present disclosure. The RCA probe 400 may include a damping layer 402, row electrodes 404, a diode array layer 406, piezo-composite material 408, a sputtered resistance layer 410, column electrodes 412, a probe face 414, and filled epoxy 416.

The damping layer 402 may be provided on a top side of the RCA probe 400. The row electrodes 404 and column electrodes 412 may be attached to opposing sides of the piezo-composite material 408 using a variety of coupling techniques. For example, the row and column electrodes 404, 412 may be imprinted directly on the piezo-composite material 408 or may be provided on a flexible circuit, which is then connected to the piezo-composite material 408. For example, channels and elements may be provided on the piezo-composite material 408 coupled by a flexible printed circuit board. The pixel piezo-composite material 408 may be monolithic or may be segmented into smaller regions.

The row electrodes 404 may include a plurality of line electrodes arranged in parallel, and the column electrodes 412 may include a plurality of line electrodes arranged in parallel. The row electrodes 404 and column electrodes 412 may be arranged substantially perpendicular or orthogonal to each other, forming an array with elements or pixels provided at the intersections of the row and column electrodes 404, 412. As explained herein, the row and column electrodes 404, 412 may generate and transmit ultrasound waves and/or may receive reflections or echoes of those ultrasound waves.

The diode array layer 406 may be fabricated between the row electrodes 404 and the piezo-composite material 408 and may aligned with the pixels. The sputtered resistance layer 410 may be provided on the surfaces of the poles of the piezo-composite material 408, such as a side surface. Filled epoxy 416 may be filled in between the sputtered resistance layer 410.

The probe face 414 may be provided beneath the column electrodes 412 and on the bottom side of the RCA probe 400. The probe face 414 may include a matching layer and a medium block. The matching layer may provide acoustic impedance matching. The medium block may be provided as a wedge.

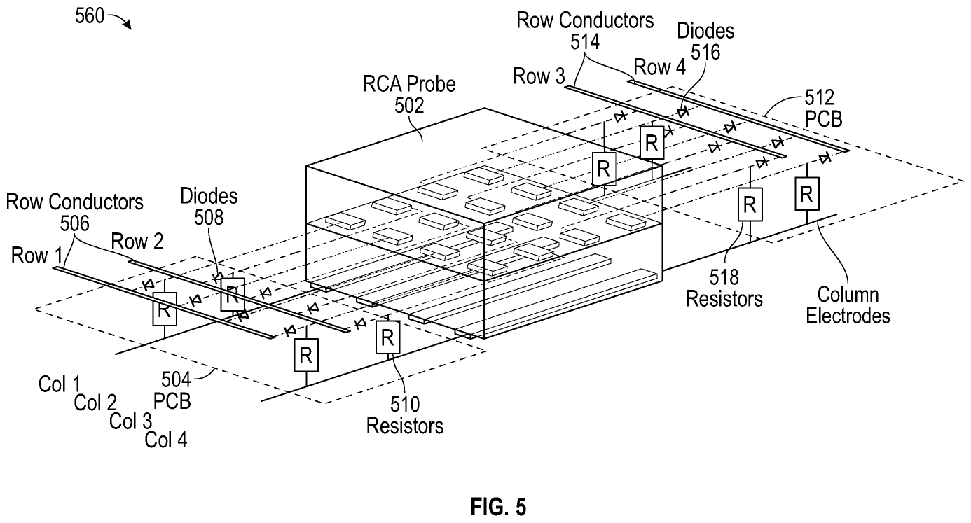

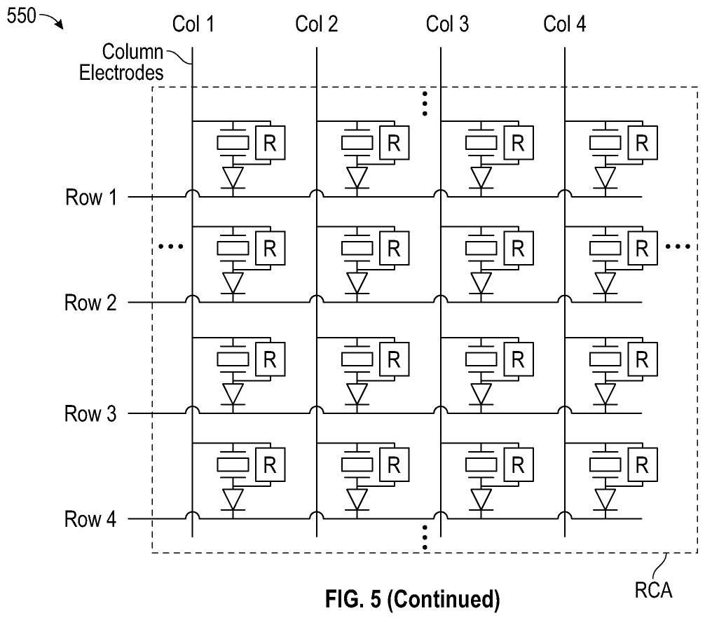

FIG. 5 illustrates an RCA probe assembly 500 according to some examples of the present disclosure. The RCA probe assembly 500 may include an RCA probe 502, a first printed circuit board (PCB) 504, a first set of row conductors 506, a first set of diodes 508, a first set of resistors 510, a second PCB 512, a second set of row conductors 514, a second set of diodes 516, and a second set of resistors 518.

The RCA probe 502 may include a damping layer, row electrodes, piezo-composite material, column electrodes, and a probe face, the RCA probe may be provided in a similar fashion as described above with reference to FIG. 4. Notably, the diodes and resistors used for eliminating cross talk among pixels are not integrated with the RCA. Instead, two PCBs 504, 512 may be provided on two sides of the RCA probe 502. Connections from the RCA probe 502 may be in or on the PCBs 504, 512.

The first set of row conductors 506 may couple a first set of piezoelectric elements formed by the piezo-electric material in the RCA probe 502 to the first set of diodes 508 and first set of resistors 510. Likewise, the second set of row conductors 514 may couple a second set of piezoelectric elements formed by the piezo-electric material in the RCA probe 502 to the second set of diodes 516 and second set of resistors 518. Schematic diagram 550 shows the circuit diagram of the RCA probe assembly 500. Hence, the RCA probe assembly 500 provides cross talk elimination using standalone diodes and resistors as described herein.

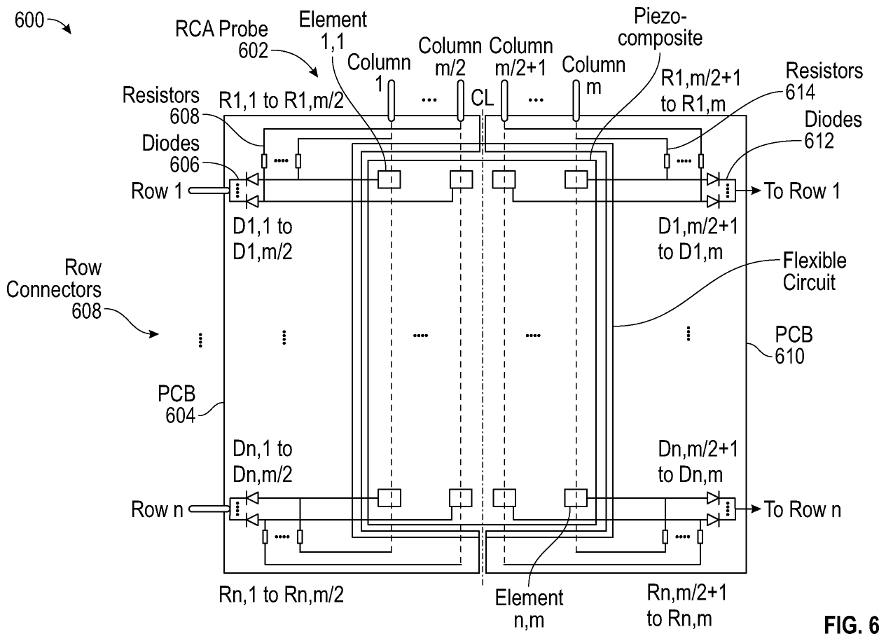

FIG. 6 illustrates an RCA probe assembly 600 with according to some examples of the present disclosure. The RCA probe assembly 600 may include a RCA probe 602, a first PCB 604, a first set of diodes 606, a first set of resistors 608, row connectors (Row11-Rown), a second PCB 610, a second set of diodes 612, and a second set of resistors 614. The RCA probe 602 may be provided in a similar fashion as described above with reference to FIG. 5 (e.g., RCA probe 502). The RCA probe 602 may include n rows and m columns (i.e., n×m array). In this example, the number of columns may be even (m=even number), and the number of rows may be equal to or greater than the number of columns (n≥m). Half of the columns of the RCA probe 602 may be coupled to the first PCB 614 (Column 1-Column (m/2)), and the other half may be coupled to the second PCB 622 (Column (m/2+1)-Column m). Connections to the PCBs 604, 610 may be provided via flexible circuits, such as a flexible PCB. n sets of m/2 diodes and resistors may be provided respectively on PCB 604 and PCB 610. The first and second PCBs 604, 610 may include the first and second set of diodes 606, 612 and first and second set of resistors (not shown), respectively. Moreover, the RCA probe assemblies without integrated diodes and resistors described herein (e.g., RCA probe assemblies 500, 600) can be more suited for use with high voltage pulsers because the diodes and resistors are not fabricated using thin film technology.

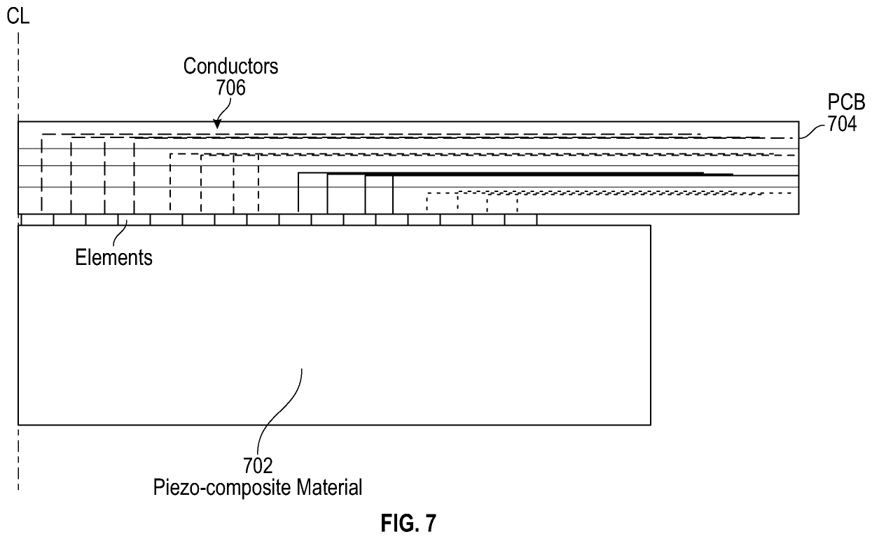

Circuit design techniques can be used to reduce the footprint of the probe assemblies described herein. For example, multi-layer flexible PCBs may be used for the connections from the RCA probe. FIG. 7 illustrates example portions of a probe assembly according to some examples of the present disclosure. FIG. 7 shows piezo-composite material 702 of a RCA probe with piezo-composite elements, as described above. FIG. 7 also shows multi-layer flexible PCB 704 with number of vertically arranged conductors 706 in the PCB 704. The conductors 706 can be used for connecting standalone diodes and resistors, as described herein.

Although the implementations of the present disclosure have been described with reference to specific example implementations, it will be evident that various modifications and changes may be made to these implementations without departing from the broader scope of the inventive subject matter. Accordingly, the specification and drawings are to be regarded in an illustrative rather than a restrictive sense. The accompanying drawings that form a part hereof show, by way of illustration, and not of limitation, specific implementations in which the subject matter may be practiced. The implementations illustrated are described in sufficient detail to enable those skilled in the art to practice the teachings disclosed herein. Other implementations may be used and derived therefrom, such that structural and logical substitutions and changes may be made without departing from the scope of this disclosure. This Detailed Description, therefore, is not to be taken in a limiting sense, and the scope of various implementations is defined only by the appended claims, along with the full range of equivalents to which such claims are entitled.

1. An inspection probe comprising:
a row-column array (RCA) including a plurality of pixels arranged in rows and columns, wherein at least one pixel of the plurality of pixels includes:
a piezo-composite element, and
a diode coupled to the piezo-composite element in series; and
a control circuit coupled to the RCA to drive the RCA in a transmission mode and to receive an electrical representation of an ultrasound wave in a reception mode.

2. The inspection probe of claim 1, wherein the at least one pixel further includes a resistor coupled to the piezo-composite element in parallel.

3. The inspection probe of claim 2, wherein the diode is provided in a diode array layer fabricated using thin-film technology.

4. The inspection probe of claim 3, wherein the diode array layer is provided between row electrodes of the RCA and a piezo-composite material including the piezo-composite element.

5. The inspection probe of claim 4, wherein the resistor is included in a sputtered resistance layer fabricated on a side surface of poles of the piezo-composite material.

6. The inspection probe of claim 2, wherein the diode is provided on a printed circuit board coupled to the RCA.

7. The inspection probe of claim 6, wherein the resistor is provided on the printed circuit board coupled to the RCA.

8. The inspection probe of claim 6, wherein the printed circuit board includes vertically arranged conductors coupling the RCA to a plurality of diodes and a plurality of resistors.

9. The inspection probe of claim 1, wherein the control circuit includes a plurality of column switches coupled to the columns and a plurality of row switches coupled to the rows, wherein the control circuit is configured to operate the RCA in a first and second transmission configuration.

10. The inspection probe of claim 1, wherein the control circuit includes a plurality of column switches coupled to the columns and a plurality of row switches coupled to the rows, wherein the control circuit is configured to operate the RCA in a first and second reception configuration.

11. A method comprising:
driving a first set of columns or a first set of rows in a row-column addressed array (RCA) to transmit at least one ultrasound wave using a transmission aperture, wherein the RCA includes a plurality of pixels and each pixel includes a piezo-composite element and a diode coupled to the piezo-composite element in series; and
receiving an electrical representation of the at least one ultrasound wave using the RCA.

12. The method of claim 11, wherein each pixel further includes resistor coupled to the piezo-composite element in parallel.

13. The method of claim 12, discharging the piezo-composite element using the resistor.

14. The method of claim 11, wherein diode is provided in a diode array layer fabricated using thin-film technology.

15. The method of claim 11, wherein the diode is provided on a printed circuit board coupled to the RCA.

16. A row-column addressed array (RCA) probe assembly, comprising:
a RCA including a plurality of row and column electrodes defining a plurality of pixels to transmit and receive ultrasound waves, wherein each pixel includes:
a piezo-composite element,
a diode coupled to the piezo-composite element in series, and
a resistor coupled to the piezo-composite element in parallel; and
a control circuit configured to operate the RCA array in a transmission mode and a reception mode,
wherein in a transmission mode, the control circuit is configured to place the plurality of row and column electrodes in different states in a first configuration providing a transmission aperture,
wherein in a reception mode, the control circuit is configured to place the plurality of row electrodes and column electrodes in different states in a second configuration providing a reception aperture.

17. The RCA probe assembly of claim 16, wherein in the transmission mode, the control circuit is configured to place the plurality of row and column electrodes in different states in a first configuration providing a transmission aperture.

18. The probe of claim 17, wherein in the reception mode, the control circuit is configured to place the plurality of row electrodes and column electrodes in different states in a second configuration providing a reception aperture.

19. The probe of claim 16, wherein the diode is provided in a diode array layer provided between the plurality of row electrodes and a piezo-composite material including the piezo-composite element.

20. The probe of claim 16, wherein the diode is provided on a printed circuit board coupled to the RCA.
